(19) United States
(12) Patent Application Publication
(10) Pub. No.: US 2006/0065970 A1
(43) Pub. Date: Mar. 30, 2006

(54) Radiating fin and method for manufacturing the same

(75) Inventors: Hiroki Uchida, Kawasaki (JP); Hideshi Tokuhira, Kawasaki (JP); Minoru Ishinabe, Kawasaki (JP); Hiroaki Date, Kawasaki (JP); Jun Taniguchi, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/020,245

(22) Filed: Dec. 27, 2004

(30) Foreign Application Priority Data
Sep. 29, 2004 (JP) 2004-284953

(51) Int. Cl. H01L 23/053

(52) U.S. Cl. 257/700

(57) ABSTRACT

A plurality of carbon fibers having a surface having a metal-plated layer (Cu-plated layer) are stood vertically on a flat plate-like provisional substrate by electrostatic flocking, and one end of the carbon fibers is provisionally adhered to the provisional substrate with an adhesive. The other end of the carbon fibers which is not provisionally adhered is contacted with a substrate (Cu plate) having a surface coated with a solder paste and, in this state, a brazing material (solder) is melted and cooled, and carbon fibers and a substrate are brazed (soldered). After completion of mechanical and thermal connection between the substrate and the carbon fibers, this is immersed in an organic solvent, and the provisionally adhered provisional substrate is peeled from the carbon fibers to manufacture a radiating fin.

### CROSS-REFERENCE TO RELATED APPLICATION

This nonprovisional application claims priority under 35 U.S.A. §119(a) on Patent Application No. 2004-284953 filed in Japan on Sep. 29, 2004, the entire contents which are hereby incorporated by reference.

### BACKGROUND OF THE INVENTION

The present invention relates to a radiating fin which radiates heat produced by electronic parts such as computer CPU chips and the like in the air, and a method for manufacturing the same, in particular, a radiating fin using a pin fin made of a carbon fiber as a fin, and a method for manufacturing the same.

In electronic devices in recent years, a heat value of electronic parts has been remarkably increased due to high integration and speedup, and it is necessary to effectively radiate heat produced from electronic parts to the outside. In order to effectively radiate heat from electronic parts into the air, it is effective to increase a radiating area. As an example of increase in a radiating area, a radiating fin used, for example, as a cooling structure of an electronic device is known.

A radiating fin is made of a metal having high heat conductivity, and can exert cooling function by sending out the air to a surface of the radiating fin from a blast fan. A radiating fin is an aluminum die-cast product which can be manufactured at the low cost, in many cases. However, when a radiating fin is an aluminum die-cast product, in order to make drawing from a mold easy, a pitch and a thickness of a fin can not be decreased. Also in the case of a radiating fin made of other material, like an aluminum die-cast product, expansion of a radiating area is limited from a viewpoint of manufacturing and cost, and this is a barrier on improvement in cooling ability.

As described above, in order to effectively radiate heat from electronic parts into the air, it is desirable that a radiating fin has high heat conductivity and a great radiating area. In order to satisfy these performances, a radiating fin having a pin fin made of a carbon fiber has been proposed (e.g. Japanese Patent Application Laid-Open 8-303978(1996)). This radiating fin has a structure in which a plurality of carbon fibers are brazed on a metal substrate to be flocked. In addition, a method for manufacturing this radiating fin is as follows: First, an adhesive is coated on a sheet-like substrate for provisional flocking, and carbon fibers are flocked to form a provisionally flocked substrate. Then, a tip of the carbon fiber flocked on the provisionally flocked substrate and a metal substrate to be flocked are fixed via a metal brazing material, to transfer-adhering the carbon fiber of the provisionally flocked substrate to a metal substrate to be flocked.

In the method of Japanese Patent Application Laid-Open 8-303978(1996), since a carbon fiber is not easily compatibilized with a metal brazing material, it is difficult to adhere a carbon fiber to a metal substrate to be flocked. In addition, even when adhered, since binding of a carbon fiber and a metal substrate to be flocked is weak, there is a problem that a carbon fiber is easily fallen from a metal substrate to be flocked due to vibration or impact. In addition, in the thus manufactured radiating fin, since a thermal resistance between a carbon fiber and a metal substrate to be flocked is great, there is also a problem that high cooling performance can not be obtained.

### BRIEF SUMMARY OF THE INVENTION

The present invention has been done in view of such the circumstances, and an object of the present invention is to provide a radiating fin having firm mechanical connection between a carbon fiber and a substrate, and a method for manufacturing the same.

Another object of the present invention is to provide a radiating fin which can exert high cooling performance, and a method for manufacturing the same.

The radiating fin of the present invention is characterized in that, in a radiating fin in which a plurality of carbon fibers are provided on a substrate, the carbon fiber is plated with a metal, and a tip of the carbon fiber is brazed with a substrate. The radiating fin of the present invention is constructed such the carbon fiber having a surface plated with a metal is brazing-fixed on the substrate. Since the surface of the carbon fiber is plated with a metal, when brazing of the carbon fiber and the substrate is performed, the surface of the carbon fiber becomes easy to be wetted with a metal brazing material, the carbon fiber is easily fixed on the substrate, and mechanical connection between the carbon fiber and the substrate is firm. In addition, a thermal resistance between the carbon fiber and the substrate is small. For this reason, since after heat from electronic parts is transmitted to the substrate, the heat is transmitted to the carbon fiber with a very small thermal resistance, and the heat is radiated into the air from the surface of the carbon fiber, cooling performance is high.

In the radiating fin of the present invention, in the aforementioned construction, it is preferable that a material for metal plating is one or a plurality of metal(s) selected from a group consisting of Cu, Ni, Au, Sn, Ag, Pd and Pt, or an alloy containing one or a plurality of metal(s) selected from the group. In the radiating fin of the present invention, a surface of the carbon fiber is plated with one or a plurality of metal(s) of Cu, Ni, Au, Sn, Ag, Pd and Pt, or an alloy containing one or a plurality of metal(s) among these elements. Therefore, wettability between a brazing material for connection is better, and a thermal resistance between the carbon fiber and the substrate is very small.

In the radiating fin of the present invention, in the aforementioned construction, it is preferable that a material of the substrate is selected from a group consisting of Cu, Al and a ceramic. The substrate is constructed of a material having better heat conductivity such as Cu, Al, a ceramic and the like. Therefore, heat from electronic parts is effectively transmitted from the substrate to the carbon fiber.

The method for manufacturing a radiating fin of the present invention is a method for manufacturing a radiating fin in which a plurality of carbon fibers are provided on a substrate, comprising a step of subjecting a plurality of carbon fibers to metal plating treatment, a step of provisionally adhering one end of the metal-plated carbon fibers to a provisional substrate, and a step of brazing-fixing to a substrate the other end of the carbon fibers which is not provisionally adhered. After one end of the carbon fibers having a surface plated with a metal is provisionally adhered to the provisional substrate, the other end of the carbon fibers is brazing-fixed to the substrate to manufacture a radiating fin. Therefore, it is easy to manufacture a radiating fin having the aforementioned properties.

The method for manufacturing a radiating fin of the present invention is a method for manufacturing a radiating fin in which a plurality of carbon fibers are provided on a substrate, comprising a step of provisionally adhering one end of a plurality of carbon fibers to a provisional substrate, a step of subjecting the other end portion of the provisionally adhered carbon fibers to metal plating treatment, and a step of brazing-fixing the other end of the carbon fibers plated with a metal to a substrate. After one end of the carbon fibers is provisionally adhered to the provisional substrate, the other end portion of the carbon fibers is subjected to metal plating treatment, and the other end of carbon fibers is brazing-fixed to the substrate to manufacture a radiating fin. Therefore, it is easy to manufacture a radiating fin having the aforementioned properties.

The above and further objects and features of the invention will more fully be apparent from the following detailed description with accompanying drawings.

### BRIEF DESCRIPTION OF THE SEVERAL VIEWS OF THE DRAWINGS

FIG. 1 is a view showing one example of construction of the radiating fin of the present invention,

FIG. 2 is a view showing another example of construction of the radiating fin of the present invention,

FIGS. 3A to 3G are a view showing one example of processes of the method for manufacturing a radiating fin of the present invention; and

FIGS. 4A to 4F are a view showing another example of processes of the method for manufacturing a radiating fin of the present invention.

### DETAILED DESCRIPTION OF THE INVENTION

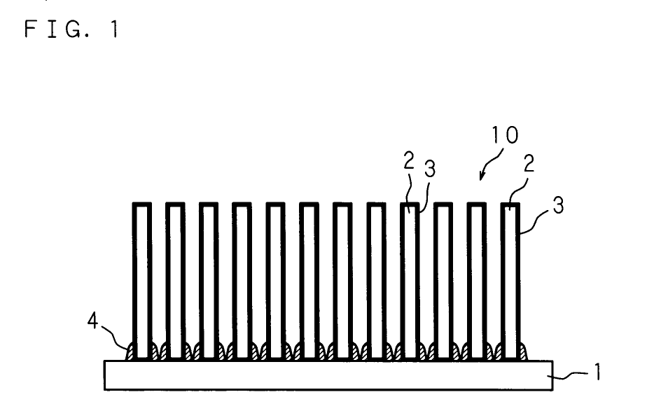

The present invention will be specifically explained below by referring to the drawings showing embodiments thereof. FIG. 1 is a view showing one example of construction of a radiating fin 10 of the present invention.

In FIG. 1, 1 is a substrate, for example, made of a Cu plate, and 2 is a plurality of carbon fibers having a surface having a metal-plated layer 3, for example, made of Cu. A tip of each carbon fiber 2 is adhered to the substrate 1 via a brazing material 4, for example, made of a solder.

As the carbon fiber 2, for example, Dialead (K223HG) manufactured by Mitsubishi Chemical Functional Products, Inc. may be used, but the carbon fiber is not limited to this as far as it is a carbon fiber having high heat conductivity. In addition, the carbon fiber 2 has a conversion diameter of 10 μm to 1 mm, and an aspect ratio of 5 to 100. When the carbon fiber 2 has such the size, it can be easily flown upon electrostatic flocking. As used herein, the “conversion diameter” is a value obtained by converting a cross-sectional area of a fiber to a diameter of a circle having the same cross-sectional area, and the “aspect ratio” is a value obtained by dividing a length of a fiber by a thickness thereof.

The radiating fin 10 of the present invention is constructed such that the carbon fiber 2 having a surface having the metal-plated layer 3 (Cu-plated layer) is brazing-fixed to the substrate 1 (Cu plate) with the brazing material 4 (solder). Since the surface of the carbon fiber 2 is plated with a metal, upon brazing between the carbon fiber 2 and the substrate 1, the metal-plated layer 3 on the surface of the carbon fiber 2 and the brazing 4 are easily wetted, the carbon fiber 2 is easily fixed to the substrate 1, and mechanical connection between the carbon fiber 2 and the substrate 1 is firm.

In addition, the metal-plated layer 3 and the brazing material 4 intervene between the carbon fiber 2 and the substrate 1, and a thermal resistance therebetween is small. For this reason, after heat from electronic parts is transmitted to the substrate 1, the heat is transmitted to the carbon fiber 2 via a very small thermal resistance, and the heat is radiated into the air from the surface of the carbon fiber 2, thus, cooling performance of the radiating fin 10 is dramatically improved.

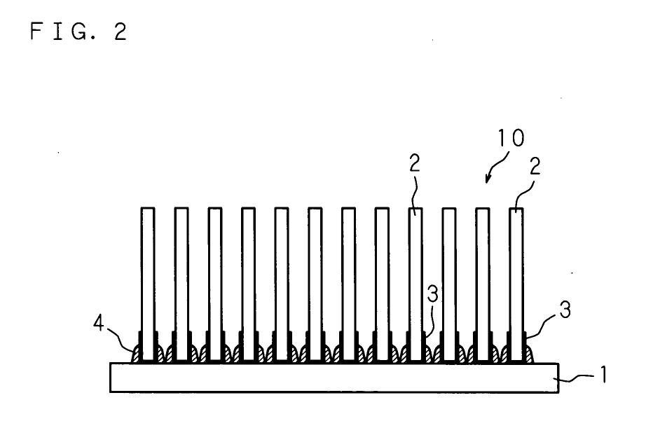

FIG. 2 is a view showing another example of construction of the radiating fin 10 of the present invention. In an example shown in FIG. 1, the metal-plated layer 3 (Cu-plated layer) is provided on a whole surface of the carbon fiber 2, but in an example in FIG. 2, the metal-plated layer 3 (Cu-plated layer) is provided only on a part (tip part) contacting with the brazing material 4 consisting of a solder. In this example shown in FIG. 2, in addition to exertion of the same effect as that of an example shown in FIG. 1, since a volume of the metal-plated layer 3 may be small, reduction in the cost is possible.

As described above, in the radiating fin 10 of the present invention, since the carbon fiber 2 plated with a metal is brazing-fixed to the substrate 1, upon brazing between the carbon fiber 2 and the substrate 1, a surface of the carbon fiber 2 is easily wetted with the metal brazing material 4, the carbon fiber 2 can be easily fixed to the substrate 1, and mechanical connection between the carbon fiber 2 and the substrate 1 can be made to be firm. In addition, since a thermal resistance between the carbon fiber 2 and the substrate 1 is small, after heat from electronic parts is transmitted to the substrate 1, the heat is transmitted to the carbon fiber 2 via a very small thermal resistance, and the heat is radiated into the air from the surface of the carbon fiber 2, thus, cooling performance can be dramatically improved.

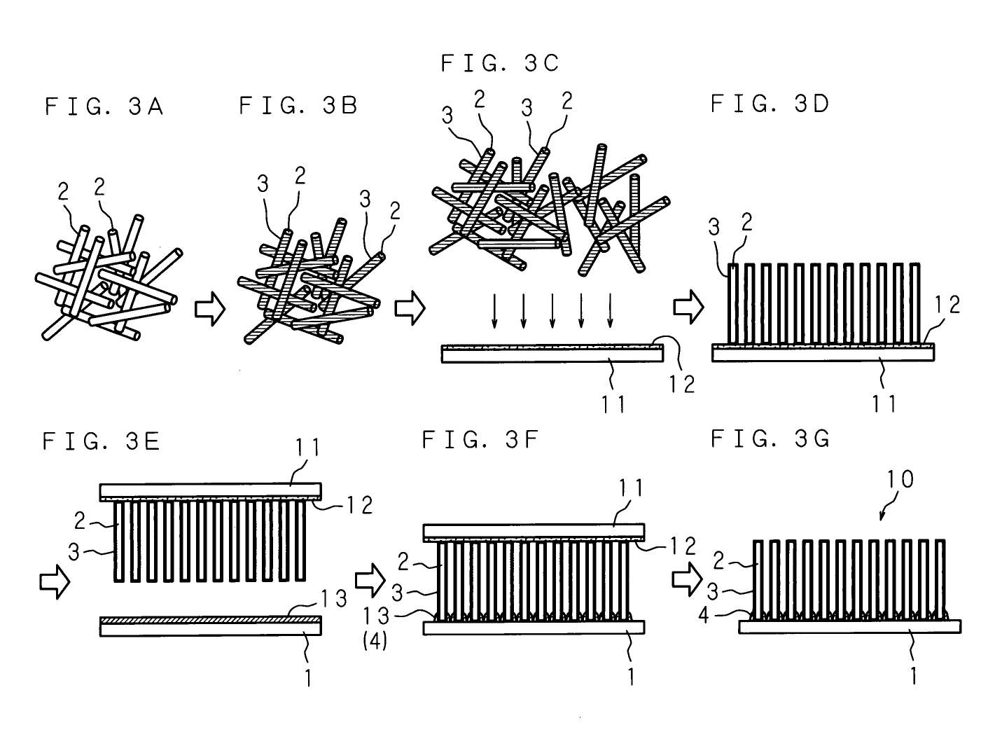

Then, a method for manufacturing a radiating fin 10 will be explained. FIGS. 3A to 3G are a view showing one example of processes of the method for manufacturing a radiating fin 10 of the present invention.

First, a plurality of carbon fibers 2 (e.g. length: 6 mm, diameter: 10 μm, heat conductivity: 620 W/mK) which have been cut short, are subjected to metal plating treatment (e.g. electroless Cu plating treatment) (FIGS. 3A, 3B). Then, the carbon fiber 2 having a metal plating (Cu plating)-treated surface with a metal-plated layer 3 (Cu-plated layer) is stood vertically on a flat plate-like provisional substrate 11 by electrostatic flocking, and one end of the carbon fiber 2 is provisionally adhered to a provisional substrate 11 with an adhesive 12 (FIGS. 3C, 3D).

As the provisional substrate 11, any provisional substrate such as a stainless plate, a metal plate such as Al, Cu and the like, and a glass cloth substrate-epoxy resin substrate having heat resistance can be used as far as it is a plate of a material having heat resistance of around 200° C. which is a soldering temperature. In addition, as the adhesive 12 for provisional fixation, a thermoplastic synthetic resin adhesive such as a polyacrylic resin, a polyurethane resin, a polyvinyl acetate resin and the like can be used, and a soluble adhesive may be used so that separation of the carbon fiber 2 and the provisional substrate 11 may be easily performed in a post-process. As the electrostatic flocking procedure, the known method (e.g. flocking method disclosed in Japanese Patent Application Publication 6-24793(1994)) can be used, and both of an up method and a down method can be used, but in view of an adhesion strength, alignment of fibers, and the is upright state of fibers, the up method is more desirable.

Then, the other end of the carbon fiber 2 which is not provisionally adhered is contacted with the substrate 1 (e.g. Cu plate) having a surface coated with a solder paste 13 as a brazing material and, in this state, the brazing material (solder) is melted and cooled to braze (solder) the carbon fiber 2 and the substrate 1 (Cu plate) (FIGS. 3E, 3F). As the brazing material, when the carbon fiber 2 is plated with Cu, and a Cu plate is used as the substrate 1, a Sn—Pb solder paste, and a Sn—Ag solder paste which are used in general packaging of electronic parts can be used. Heating of the brazing material (solder) in this state can be performed using a hot plate, an infrared-ray reflow furnace, a hot blast reflow furnace or the like and, in any case, the carbon fiber 2 and the substrate 1 (Cu plate) can be securely connected by cooling after heating to around a melting point of a solder+(30 to 100)° C.

Finally, after completion of mechanical and thermal connection of the substrate 1 (Cu plate) and the carbon fiber 2, this is immersed in a solvent such as ethanol, acetone and the like to peel the provisionally adhered provisional substrate 11 from the carbon fiber 2, thereby, the radiating fin 10 as shown in FIG. 1 is manufactured (FIG. 3G). In addition, when an adhesive made of a thermoplastic resin is used as the adhesive 12, this may be heated again in order to peel the provisional substrate 11 from the carbon fiber 2.

In such the method for manufacturing a radiating fin of the present invention, a plurality of carbon fibers 2 are subjected to metal plating treatment, one end of the metal-plated carbon fiber 2 is provisionally adhered to the provisional substrate 11, the other end of the carbon fibers 2 which is not provisionally adhered is brazing-fixed to the substrate 1, thereby, the radiating fin 10 is manufactured, therefore, a radiating fin exerting the aforementioned effect can be easily manufactured.

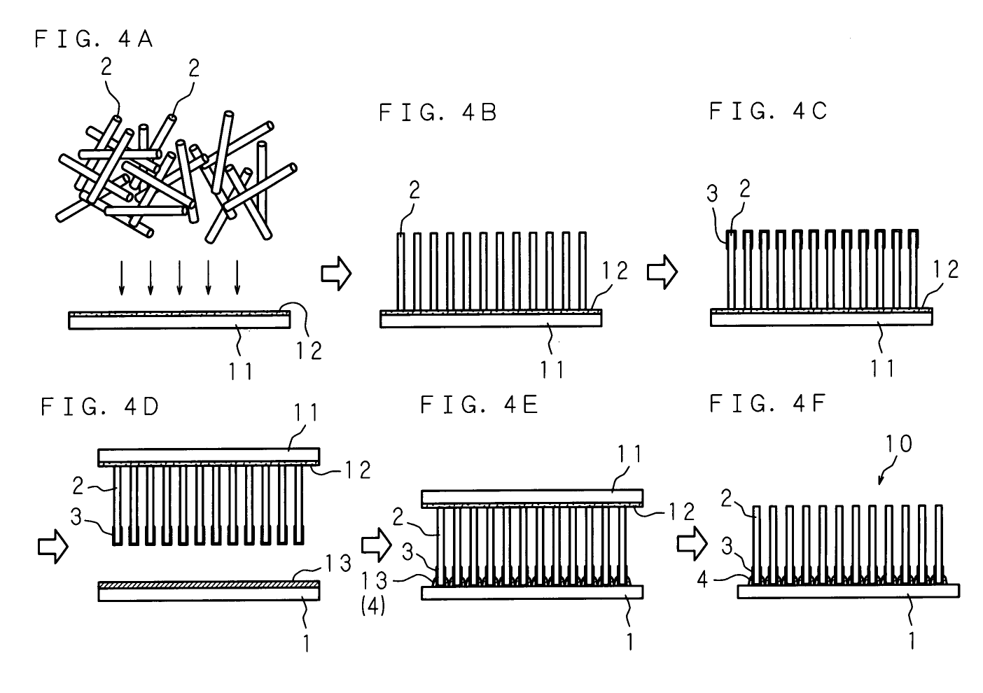

FIGS. 4A to 4F are a view showing another example of processes of the method for manufacturing a radiating fin 10 of the present invention. First, a plurality of shortly cut carbon fibers 2 (e.g. length: 6 mm, diameter: 10 μm, heat conductivity: 620 W/mK) are prepared, those carbon fibers 2 are stood vertically on a flat plate-like provisional substrate 11 by electrostatic flocking, and one end of the carbon fiber 2 is provisionally adhered to the provisional substrate 11 with an adhesive 12 (FIGS. 4A, 4B). A material of the provisional substrate 11, a material of the adhesive 12, and a procedure of electrostatic flocking are the same as those shown in FIGS. 3A to 3D.

Then, the other end portion of the carbon fiber 2 which is not provisionally adhered is immersed into a plating solution to perform metal plating treatment (e.g. electrolytic Cu plating treatment), to form a metal-plated layer 3 (Cu-plated layer) on a surface of the other end portion of the carbon fiber 2 (FIG. 4C). Then, the other end of the carbon fiber 2 which is not provisionally adhered and on which the metal-plated layer 3 (Cu-plated layer) is formed, is contacted with a substrate 1 (e.g. Cu plate) having a surface coated with a solder paste 13 as a brazing material and, in this state, the brazing material (solder) is melted and cooled, to braze (solder) the carbon fiber 2 and the substrate 1 (Cu plate) (FIGS. 4D, 4E). A material of the brazing material, and a procedure of heating the brazing material are the same as those shown in FIGS. 3E and 3F.

Finally, after completion of mechanical and thermal connection between the substrate 1 (Cu plate) and the carbon fiber 2, this is immersed into a solvent such as ethanol, acetone and the like to peel the provisionally adhered provisional substrate 11 from the carbon fiber 2, thereby, the radiating fin 10 as shown in FIG. 2 is manufactured (FIG. 4F). When an adhesive made of a thermoplastic resin is used as the adhesive 12, this may be heated again in order to peel the provisional substrate 11 from the carbon fiber 2.

In such the method for manufacturing a radiating fin of the present invention, since one end of the carbon fiber 2 is provisionally adhered to the provisional substrate 11, the other end portion of the provisionally adhered carbon fiber 2 is subjected to metal plating treatment, and the other end of the carbon fiber 2 plated with a metal is brazing-fixed to the substrate 1 to manufacture the radiating fin 10, a radiating fin exerting the aforementioned effect can be easily manufactured.

In the aforementioned example of a method, the solder paste 13 is provided on the substrate 1 (Cu plate), but the solder paste 13 may be provided on the other end of the carbon fiber 2 which is not provisionally adhered, and the carbon fiber 2 may be connected to the substrate 1 (Cu plate).

In the aforementioned example, metal plating on the carbon fiber 2 is Cu plating. However, this is merely one example and, as a material of metal plating, one or a plurality of metal(s) selected from the group consisting of Cu, Ni, Au, Sn, Ag, Pd and Pt, or an alloy containing one or a plurality of metal(s) selected from the group can be used. In the radiating fin 10 of the present invention, since as a material of metal plating, one or a plurality of a metal(s) selected from the group consisting of Cu, Ni, Au, Sn, Ag, Pd and Pt, or an alloy containing one or a plurality of a metal(s) selected from the group is (are) used, wettability with a brazing material for connection is better, and a thermal resistance between the carbon fiber 2 and the substrate 1 can be very small.

As the substrate 1, a Cu plate is used, but this is merely one example, and an Al plate and a ceramic plate having better heat conductivity may be also used. In addition, a carbon plate which has been subjected to surface treatment such as Cu plating, Ni/Au plating or the like may be used. In the radiating fin 10 of the present invention, since as a material of the substrate 1, a material selected from the group consisting of Cu, Al and a ceramic is used, heat conductivity of the substrate 1 is better, and heat from electric parts can be effectively transmitted from the substrate 1 to the carbon fiber 2.

As this invention may be embodied in several forms without departing from the split of essential characteristics thereof, the present embodiment is therefore, illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. A radiating fin in which a plurality of carbon fibers are provided on a substrate, wherein the carbon fibers are metal-plated, and a tip of the carbon fibers is brazed to the substrate.

2. The radiating fin according to claim 1, wherein a material for the metal plating is one or a plurality of metal(s) selected from a group consisting of Cu, Ni, Au, Sn, Ag, Pd and Pt, or an alloy containing one or a plurality of metal(s) selected from the group.

3. The radiating fin according to claim 1, wherein a material of the substrate is selected from a group consisting of Cu, Al and a ceramic.

4. The radiating fin according to claim 2, wherein a material of the substrate is selected from a group consisting of Cu, Al and a ceramic.

5. A method for manufacturing a radiating fin in which a plurality of carbon fibers are provided on a substrate, comprising:
a step of subjecting a plurality of carbon fibers to metal plating treatment:
a step of provisionally adhering one end of the metal-plated carbon fibers to a provisional substrate; and
a step of brazing-fixing to a substrate the other end of the carbon fibers which is not provisionally adhered.

6. A method for manufacturing a radiating fin in which a plurality of carbon fibers are provided on a substrate, comprising:
a step of provisionally adhering one end of a plurality of carbon fibers to a provisional substrate;
a step of subjecting the other end portion of the provisionally adhered carbon fibers to metal plating treatment; and
a step of brazing-fixing the other end of the carbon fibers plated with a metal to a substrate.
